(19) United States
(12) Patent Application Publication
(10) Pub. No.: US 2024/0313170 A1
(43) Pub. Date: Sep. 19, 2024

(54) WAVELENGTH CONVERSION MATRIX AND MANUFACTURING METHOD FOR THE SAME, AND DISPLAY

(71) Applicant: RAYSOLVE OPTOELECTRONICS (SUZHOU) CO., LTD., Suzhou (CN)

(72) Inventors: Xu ZHANG, Suzhou (CN); Wing Cheung CHONG, Suzhou (CN); Kei May LAU, Suzhou (CN)

(73) Assignee: RAYSOLVE OPTOELECTRONICS (SUZHOU) CO., LTD., Suzhou (CN)

(21) Appl. No.: 18/650,581

(22) Filed: Apr. 30, 2024

Related U.S. Application Data
(63) Continuation-in-part of application No. PCT/CN2022/126452, filed on Oct. 20, 2022.
(63) Continuation-in-part of application No. PCT/CN2022/126437, filed on Oct. 20, 2022.

(30) Foreign Application Priority Data
Nov. 1, 2021 (CN) 202111285591.8
Nov. 1, 2021 (CN) 202111286417.5

(51) Int. Cl. H01L 33/50; H01L 25/075; H01L 27/15

(52) U.S. Cl. CPC H01L 33/505; H01L 25/0753; H01L 27/156; H01L 33/504; H01L 2933/0041

(57) ABSTRACT

A wavelength conversion matrix includes: at least one wavelength conversion layer that is dry-etchable, where each wavelength conversion layer of the at least one wavelength conversion layer includes a mask area and a non-mask area, the non-mask area is a hollow area, the wavelength conversion layer is configured to superimpose a self-luminous pixel of a display to emit light with a set light wavelength. In the present disclosure, patterning of a wavelength conversion material may be realized by dry etching, thereby improving a resolution of the wavelength conversion matrix.

### CROSS-REFERENCE TO RELATED APPLICATIONS

The present disclosure is a continuation-in-part of International Application No. PCT/CN2022/126437, filed on Oct. 20, 2022, which claims priority to Chinese Patent Application No. 202111285591.8, filed on Nov. 1, 2021. The present disclosure is also a continuation-in-part of International Application No. PCT/CN2022/126452, filed on Oct. 20, 2022, which claims priority to Chinese Patent Application No. 202111286417.5, filed on Nov. 1, 2021. All of the aforementioned patent applications are hereby incorporated by reference in their entireties.

### TECHNICAL FIELD

The present disclosure relates to the field of micro-display technologies, and in particular, to a wavelength conversion matrix and a manufacturing method for the same, and a display.

### BACKGROUND

In a related art, there are many researches on a manufacturing process of a single-color Micro Light-Emitting Diode (Micro-LED) micro-display device, and the manufacturing process is also relatively mature. At present, a preparation of a full-color Micro-LED display mainly adopts assembling of three primary colors LED chips, and assembling of three primary colors faces a huge problem in an aspect of mass transfer.

It is a more convenient and feasible method for realizing full-color display by preparing a display device through a photoluminescent material such as a phosphor light conversion layer or a quantum dot color conversion layer. However, at present, there is a problem of poor display effect of a display device, prepared by a method for preparing a display device through a photoluminescent material such as a phosphor light conversion layer or a quantum dot color conversion layer.

### SUMMARY

A main objective of the present disclosure is to provide a wavelength conversion matrix and a manufacturing method for the same, and a display, to overcome disadvantages in the related art.

In order to achieve the above objective, technical solutions adopted in the present disclosure include the following contents.

Embodiments of the present disclosure provide a manufacturing method for a wavelength conversion matrix, which includes: disposing a wavelength conversion layer on a surface of a substrate; disposing a mask on a surface of the wavelength conversion layer; and removing a remaining part of the wavelength conversion layer except a part of the wavelength conversion layer protected by the mask through dry etching to form a wavelength conversion matrix.

Embodiments of the present disclosure further provide a wavelength conversion matrix, which includes: at least one wavelength conversion layer that is dry-etchable. Each wavelength conversion layer of the at least one wavelength conversion layer includes a mask area and a non-mask area, the non-mask area is a hollow area, the wavelength conversion layer is configured to superimpose a self-luminous pixel of a display to emit light with a set light wavelength.

Embodiments of the present disclosure further provide a display, which includes: a substrate, having a first surface on which a plurality of self-luminous pixels are distributed; and a wavelength conversion matrix, including at least one wavelength conversion layer disposed on the first surface of the substrate. Each wavelength conversion layer of the at least one wavelength conversion layer includes a mask protection area and a dry etching area, and the mask protection area covers part of or all of the plurality of self-luminous pixels.

According to the manufacturing method for a wavelength conversion matrix, the wavelength conversion matrix and the display provided by embodiments of the present disclosure, a pattern of a wavelength conversion layer is obtained through dry etching, which may improve a resolution of an obtained wavelength conversion matrix, thereby improving a display effect of a display device.

### BRIEF DESCRIPTION OF THE DRAWINGS

FIG. 1a is a schematic structural diagram of a manufacturing principle of a wavelength conversion matrix in the prior art.

FIG. 1b is a schematic structural diagram of another manufacturing principle of a wavelength conversion matrix in the prior art.

FIG. 2 is a schematic structural diagram of a wavelength conversion matrix according to an embodiment of the present disclosure.

FIG. 3a to FIG. 3k are schematic structural diagrams corresponding to a plurality of intermediate structures during a manufacturing process of a wavelength conversion matrix according to an embodiment of the present disclosure.

FIG. 4 is a schematic diagram of a distribution pattern of self-luminous pixels 20 according to an embodiment of the present disclosure.

FIG. 5a, FIG. 5b and FIG. 5c are schematic diagrams of arrangement structures of red, green and blue pixels in full-color pixels.

FIG. 6 is a schematic structural diagram of a display according to an embodiment of the present disclosure.

FIG. 7a to FIG. 7l are schematic structural diagrams corresponding to a plurality of intermediate structures during a manufacturing process of a display according to an embodiment of the present disclosure.

### DETAILED DESCRIPTION OF THE EMBODIMENTS

At present, it is a more convenient and feasible method for realizing full-color display by preparing a display device through a photoluminescent material such as a phosphor light conversion layer or a quantum dot color conversion layer. The phosphor has low efficiency, a large full width at half maximum, a poor color purity, a poor display effect and a large particle size, which is not suitable for micro-display with a small pixel point. A quantum dot material has advantages of concentrated luminescence spectrum, high color purity, and simple adjustment of luminescence color through a size, a structure or a composition of the quantum dot material, and color gasmut and a color restoration capability of a display apparatus may be effectively improved by using these advantages in the display apparatus.

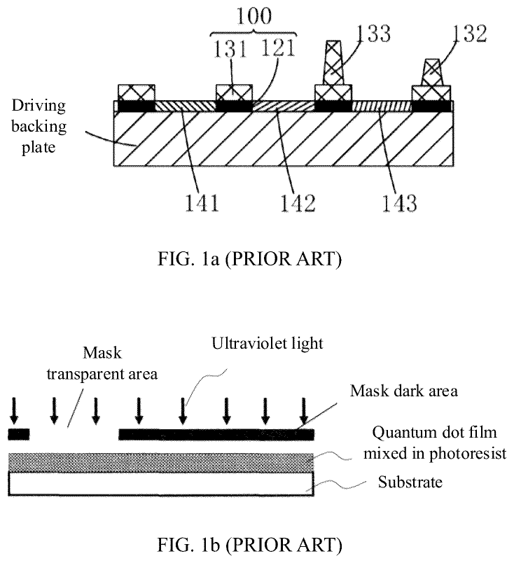

The prior art 1 (U.S. Pat. No. 9,904,097B2, U.S. Pat. No. 8,459,855B2) discloses a manufacturing method for a wavelength conversion matrix. As shown in FIG. 1a, a structure in FIG. 1a includes: a driving backing plate; a barrier wall 100 including a black barrier wall 121 and a transparent barrier wall 131; spacers 132/133; and red, green and blue quantum dot layers 141/142/143. In the prior art 1, the barrier wall structure is built by using a transparent photoresist, thereby helping to limit distribution of the quantum dot layers made by a method of gas injection. Specifically, a wavelength conversion material is directly coated on a display panel and patterned, and a photoluminescent material is dispersed in a low-viscosity solvent and then printed on the display panel in a gas injection manner. However, due to a diffusion effect of the low-viscosity solvent, a thickness of the material is difficult to accumulate, so that photoluminescent conversion is insufficient, thereby affecting display quality. Moreover, a printing process requires high alignment accuracy and is time-consuming, therefore, when a resolution and a pixel density of a micro-display screen are continuously increased, production efficiency of the printing process may be problematic.

As shown in FIG. 1b, the prior art 2 (U.S. Pat. No. 9,690,135B2) discloses that a wavelength conversion material is coated on a transparent substrate and patterned, and then the patterned structure is covered on a display panel by a flip-chip method. A photoluminescent material is dispersed in a photoresist and patterned by a photolithography method, production efficiency is improved greatly, and light conversion efficiency is also improved due to the improvement of a thickness of the material. However, a resolution is limited due to a serious scattering phenomenon of a light conversion material, and in order to improve the resolution and obtain a patterned structure lower than 5 μm, a concentration of the photoluminescent material must be controlled at a lower level, but corresponding absorption and conversion characteristics may degrade. Therefore, it is very challenging to balance resolution and conversion efficiency in this method.

In view of deficiencies in the prior art, the applicant of the present disclosure has provided the technical solutions of the present disclosure through long-term research and extensive practices. The technical solutions, implementation processes and principles of the technical solutions, and the like may be further explained as follows.

Embodiments of the present disclosure provide a manufacturing method for a wavelength conversion matrix, which includes:
providing a substrate, and disposing a wavelength conversion layer on a surface of the substrate;
disposing a mask on a surface of the wavelength conversion layer; and
removing a remaining part of the wavelength conversion layer except a part of the wavelength conversion layer protected by the mask through dry etching to form a wavelength conversion matrix.

In a specific embodiment, the mask is a hard mask, and the hard mask is any one or a combination of a dielectric material mask, a photoresist mask and a metal mask, but is not limited thereto.

In a specific embodiment, a material of the dielectric material mask includes any one or a combination of titanium dioxide, zirconium dioxide, silicon dioxide, silicon nitride and aluminum oxide, but is not limited thereto.

In a specific embodiment, a material of the metal mask includes any one or a combination of cadmium, aluminum, nickel, gold, copper, chromium, titanium and platinum, but is not limited thereto.

In a specific embodiment, a material of the photoresist mask includes a positive photoresist or a negative photoresist.

In a specific embodiment, the dry etching includes physical etching, chemical etching, or physical and chemical etching, but is not limited thereto.

In a specific embodiment, the physical etching includes ion beam etching, and an etching gas used in the ion beam etching includes an inert gas, such as argon, but is not limited thereto.

In a specific embodiment, the chemical etching includes plasma etching, and an etching gas used in the plasma etching includes a fluorine-containing gas, such as sulfur hexafluoride, carbon tetrafluoride, trifluoromethane, but is not limited thereto.

In a specific embodiment, the physical and chemical etching includes reactive ion etching, and an etching gas used in the reactive ion etching includes a gas containing fluorine, chlorine or sulfur, for example, may be any one or a combination of chlorine, boron trichloride, sulfur hexafluoride, carbon tetrafluoride and an inert gas, but is not limited thereto.

In a specific embodiment, the manufacturing method further includes:
disposing a passivation layer on the surface of the substrate to make the passivation layer fill a gap of the wavelength conversion matrix, and make a surface of the passivation layer be flush with or lower than the surface of the wavelength conversion layer.

In a specific embodiment, the wavelength conversion layer includes a first wavelength conversion layer, and the manufacturing method specifically includes:
disposing the first wavelength conversion layer on the surface of the substrate;
disposing a first mask on a predetermined area (a first area) of a surface of the first wavelength conversion layer; and
removing a remaining part of the first wavelength conversion layer except a part of the first wavelength conversion layer protected by the first mask through dry etching to form the wavelength conversion matrix, where the first wavelength conversion layer is configured to superimpose a first self-luminous pixel of a display to emit light with a first light wavelength.

In a specific embodiment, the manufacturing method further includes:
disposing a first filter layer on the surface of the substrate before disposing the first wavelength conversion layer.

The first wavelength conversion layer at least covers the first filter layer, the first mask corresponds to the first filter layer, and the first filter layer allows the light with the first light wavelength to pass through.

In a specific embodiment, the wavelength conversion layer further includes a second wavelength conversion layer, and the manufacturing method further includes:
disposing the second wavelength conversion layer on the surface of the substrate after removing the remaining part of the first wavelength conversion layer except the part of the first wavelength conversion layer protected by the first mask through dry etching;
disposing a second mask on a second area of a surface of the second wavelength conversion layer; and
removing a remaining part of the second wavelength conversion layer except a part of the second wavelength conversion layer protected by the second mask through dry etching to form the wavelength conversion matrix, where the second wavelength conversion layer is configured to superimpose a second self-luminous pixel of the display to emit light with a second light wavelength.

In a specific embodiment, wavelengths of light emitted by the first self-luminous pixel and by the second self-luminous pixel are the same or different, photoluminescent materials contained in the first wavelength conversion layer and in the second wavelength conversion layer are the same or different, and light with the first light wavelength is different from light with the second light wavelength.

In a specific embodiment, the manufacturing method further includes: disposing a first filter layer and a second filter layer on the surface of the substrate before disposing the first wavelength conversion layer.

The first wavelength conversion layer at least covers the first filter layer, and the first mask corresponds to the first filter layer;
the second wavelength conversion layer at least covers the second filter layer, and the second mask corresponds to the second filter layer; and
the first filter layer allows the light with the first light wavelength to pass through, and the second filter layer allows the light with the second light wavelength to pass through.

In a specific embodiment, the wavelength conversion layer further includes a third wavelength conversion layer, and the manufacturing method further includes:
disposing the third wavelength conversion layer on the surface of the substrate after removing the remaining part of the second wavelength conversion layer except the part of the second wavelength conversion layer protected by the second mask through dry etching;
disposing a third mask on a third area of a surface of the third wavelength conversion layer; and
removing a remaining part of the third wavelength conversion layer except a part of the third wavelength conversion layer protected by the third mask through dry etching to form the wavelength conversion matrix, where the third wavelength conversion layer is configured to superimpose a third self-luminous pixel of the display to emit light with a third light wavelength.

In a specific embodiment, wavelengths of light emitted by the first self-luminous pixel, by the second self-luminous pixel and by the third self-luminous pixel are the same or different, photoluminescent materials contained in the first wavelength conversion layer, in the second wavelength conversion layer and in the third wavelength conversion layer are the same or different, and the light with the first light wavelength, the light with the second light wavelength and the light with the third light wavelength are different.

In a specific embodiment, the manufacturing method further includes:
disposing a first filter layer, a second filter layer and a third filter layer on the surface of the substrate before disposing the first wavelength conversion laye.

The first wavelength conversion layer at least covers the first filter layer, and the first mask corresponds to the first filter layer;
the second wavelength conversion layer at least covers the second filter layer, and the second mask corresponds to the second filter layer;
the third wavelength conversion layer at least covers the third filter layer, and the third mask corresponds to the third filter layer; and
the first filter layer allows the light with the first light wavelength to pass through, the second filter layer allows the light with the second light wavelength to pass through and the third filter layer allows the light with the third light wavelength to pass through.

In a specific embodiment, the manufacturing method further includes: removing the mask after forming the wavelength conversion matrix.

The manufacturing method for the wavelength conversion matrix may be used as a manufacturing method for a display, where a plurality of self-luminous pixels are distributed on the surface of the substrate, and the mask is disposed corresponding to at least part of the plurality of self-luminous pixels.

Specifically, embodiments of the present disclosure further provide a manufacturing method for a display, which includes:
providing a substrate, having a first surface on which a plurality of self-luminous pixels are distributed;
disposing a wavelength conversion layer on the first surface of the substrate;
disposing a mask on a surface of the wavelength conversion layer, where the mask is disposed corresponding to part of or all of the plurality of self-luminous pixels; and
removing a remaining part of the wavelength conversion layer except a part of the wavelength conversion layer protected by the mask through dry etching to form a wavelength conversion matrix.

In a specific embodiment, the disposing a wavelength conversion layer on the first surface of the substrate includes: coating a wavelength conversion material on the first surface of the substrate, and curing the wavelength conversion material by ultraviolet irradiation or thermal baking to form the wavelength conversion layer.

For a specific material of the mask and a dry etching manner, refer to above descriptions of the manufacturing method for the wavelength conversion matrix.

In a specific embodiment, the disposing a wavelength conversion layer on the first surface of the substrate includes: first disposing an etching barrier layer on the first surface of the substrate, and then disposing the wavelength conversion layer on a surface of the etching barrier layer.

In a specific embodiment, the manufacturing method further includes: forming a passivation layer on the first surface of the substrate, where a gap of the wavelength conversion matrix is filled with the passivation layer, and a surface of the passivation layer is flush with or lower than the surface of the wavelength conversion layer.

In a specific embodiment, the plurality of self-luminous pixels include a first self-luminous pixel, and the wavelength conversion layer includes a first wavelength conversion layer. The disposing a wavelength conversion layer on the first surface of the substrate includes: disposing the first wavelength conversion layer on the first surface of the substrate, where the disposing a mask on a surface of the wavelength conversion layer includes: disposing a first mask in a predetermined area (a first area) of a surface of the first wavelength conversion layer. The predetermined area is disposed corresponding to the first self-luminous pixel. The removing a remaining part of the wavelength conversion layer except a part of the wavelength conversion layer protected by the mask through dry etching to form a wavelength conversion matrix includes: removing a remaining part of the first wavelength conversion layer except a part of the first wavelength conversion layer protected by the first mask through dry etching to form the wavelength conversion matrix. The first self-luminous pixel is configured to superimpose the first wavelength conversion layer to emit light with a first light wavelength.

In a specific embodiment, the manufacturing method further includes: disposing a first filter layer on the first wavelength conversion layer. The first filter layer allows the light with the first light wavelength to pass through.

In a specific embodiment, the plurality of self-luminous pixels include a first self-luminous pixel and a second self-luminous pixel, and the wavelength conversion layer includes a first wavelength conversion layer and a second wavelength conversion layer. The disposing a wavelength conversion layer on the first surface of the substrate includes: disposing the first wavelength conversion layer on the first surface of the substrate, where the disposing a mask on a surface of the wavelength conversion layer includes: disposing a first mask in a first area of a surface of the first wavelength conversion layer. The first area is disposed corresponding to the first self-luminous pixel. The removing a remaining part of the wavelength conversion layer except a part of the wavelength conversion layer protected by the mask through dry etching to form a wavelength conversion matrix includes: removing a remaining part of the first wavelength conversion layer except a part of the first wavelength conversion layer protected by the first mask through dry etching. The disposing a wavelength conversion layer on the first surface of the substrate further includes: disposing the second wavelength conversion layer on the first surface of the substrate, where the disposing a mask on a surface of the wavelength conversion layer further includes: disposing a second mask in a second area of a surface of the second wavelength conversion layer. The second area is disposed corresponding to the second self-luminous pixel. The removing a remaining part of the wavelength conversion layer except a part of the wavelength conversion layer protected by the mask through dry etching to form a wavelength conversion matrix further includes: removing a remaining part of the second wavelength conversion layer except a part of the second wavelength conversion layer protected by the second mask through dry etching to form the wavelength conversion matrix. The first self-luminous pixel is configured to superimpose the first wavelength conversion layer to emit light with a first light wavelength, and the second self-luminous pixel is configured to superimpose the second wavelength conversion layer to emit light with a second light wavelength.

In a specific embodiment, wavelengths of light emitted by the first self-luminous pixel and by the second self-luminous pixel are the same or different, photoluminescent materials contained in the first wavelength conversion layer and in the second wavelength conversion layer are the same or different, and the light with the first light wavelength is different from the light with the second light wavelength.

In a specific embodiment, the manufacturing method further includes: disposing a first filter layer and a second filter layer on the first wavelength conversion layer and the second wavelength conversion layer respectively. The first filter layer allows the light with the first light wavelength to pass through, and the second filter layer allows the light with the second light wavelength to pass through.

In a specific embodiment, the plurality of self-luminous pixels further include a third self-luminous pixel, and the wavelength conversion layer furthrer includes a third wavelength conversion layer. The disposing a wavelength conversion layer on the first surface of the substrate further includes: disposing the third wavelength conversion layer on the first surface of the substrate, where the disposing a mask on a surface of the wavelength conversion layer further includes: disposing a third mask in a third area of a surface of the third wavelength conversion layer. The third area is disposed corresponding to the third self-luminous pixel. The removing a remaining part of the wavelength conversion layer except a part of the wavelength conversion layer protected by the mask through dry etching to form a wavelength conversion matrix further includes: removing a remaining part of the third wavelength conversion layer except a part of the third wavelength conversion layer protected by the third mask through dry etching to form the wavelength conversion matrix. The third self-luminous pixel is configured to superimpose the third wavelength conversion layer to emit light with a third light wavelength.

In a specific embodiment, wavelengths of light emitted by the first self-luminous pixel, by the second self-luminous pixel and by the third self-luminous pixel are the same or different, photoluminescent materials contained in the first wavelength conversion layer and in the second wavelength conversion layer and in the third wavelength conversion layer are the same or different, and the light with the first light wavelength, the light with the second light wavelength and the light with the third light wavelength are different.

In a specific embodiment, the manufacturing method further includes: disposing a first filter layer, a second filter layer and a third filter layer on the first wavelength conversion layer, the second wavelength conversion layer and the third wavelength conversion layer respectively. The first filter layer allows the light with the first light wavelength to pass through, the second filter layer allows the light with the second light wavelength to pass through, and the third filter layer allows the light with the third light wavelength to pass through.

In a specific embodiment, the manufacturing method further inlcudes: removing the mask after forming the wavelength conversion matrix.

Embodiments of the present disclosure further provide a wavelength conversion matrix, which includes: at least one wavelength conversion layer that is dry-etchable, where each wavelength conversion layer of the at least one wavelength conversion layer includes a mask area and a non-mask area, the non-mask area is a hollow area obtained through dry etching, and the wavelength conversion layer is configured to superimpose a self-luminous pixel of a display to emit light with a set light wavelength.

In a specific embodiment, the at least one wavelength conversion layer includes a first wavelength conversion layer, and the first wavelength conversion layer is configured to superimpose a first self-luminous pixel of the display to emit light with a first light wavelength.

In a specific embodiment, a first filter layer is disposed on the first wavelength conversion layer, and the first filter layer allows the light with the first light wavelength to pass through.

In a specific embodiment, the at least one wavelength conversion layer further includes a second wavelength conversion layer, and the second wavelength conversion layer is configured to superimpose a second self-luminous pixel of the display to emit light with a second light wavelength.

Wavelengths of light emitted by the first self-luminous pixel and by the second self-luminous pixel are the same or different, photoluminescent materials contained in the first wavelength conversion layer and in the second wavelength conversion layer are the same or different, and the light with the first light wavelength is different from the light with the second light wavelength.

In a specific embodiment, a first filter layer and a second filter layer are respectively disposed on the first wavelength conversion layer and the second wavelength conversion layer, the first filter layer allows the light with the first light wavelength to pass through, and the second filter layer allows the light with the second light wavelength to pass through.

In a specific embodiment, the at least one wavelength conversion layer further includes a thrid wavelength conversion layer, which is configured to superimpose a third self-luminous pixel of the display to emit light with a third light wavelength.

Wavelengths of light emitted by the first self-luminous pixel, by the second self-luminous pixel and by the third self-luminous pixel are the same or different, photoluminescent materials contained in the first wavelength conversion layer, in the second wavelength conversion layer and in the third wavelength conversion layer are the same or different, and the light with the first light wavelength, the light with the second light wavelength and the light with the third light wavelength are different.

In a specific embodiment, a first filter layer, a second filter layer and a third filter layer are respectively disposed on the first wavelength conversion layer, the second wavelength conversion layer and the third wavelength conversion layer, the first filter layer allows the light with the first light wavelength to pass through, the second filter layer allows the light with the second light wavelength to pass through, and the third filter layer allows the light with the third light wavelength to pass through.

In a specific embodiment, the first filter layer, the second filter layer and the third filter layer include an organic color filter photoresist, an inorganic distributed drag reflector or the like, but are not limited thereto.

In a specific embodiment, a wavelength conversion material contained in the wavelength conversion layer includes a photoluminescent material, a polymer film material and a solvent.

In a specific embodiment, the photoluminescent material includes a phosphor or a quantum dot. The phosphor may be yttrium aluminum garnet, cerium phosphor, (oxygen) nitride phosphor, silicate phosphor, Mn⁴⁺ activated fluoride phosphor, etc. The quantum dot may be a group II-VI compound quantum dot (such as cadmium sulfide, cadmium selenide, cadmium telluride, zinc oxide, zinc selenide, zinc telluride, etc.), a group III-V compound quantum dot (such as gallium arsenide, gallium phosphide, gallium antimonide, mercury sulfide, mercury selenide, mercury antimonide, indium arsenide, indium phosphide, indium antimonide, aluminum arsenide, aluminum phosphide, aluminum antimonide, etc.) and a perovskite quantum dot. Of course, the photoluminescent material may also be an organic dye or the like.

In a specific embodiment, the polymer film material includes, but is not limited to, acrylic acid, polyethylene or resin.

In a specific embodiment, the solvent is at least used to assist in dissolving the photoluminescent material into the polymer film material, and the solvent includes, but is not limited to, propylene glycol methyl ether acetate, toluene or alcohol.

In a specific embodiment, a passivation layer is further disposed in the non-mask area, and a surface of the passivation layer is flush with or lower than a surface of the wavelength conversion layer.

In a specific embodiment, a material of the passivation layer includes any one or a combination of an organic black matrix photoresist, a color filter photoresist and a polyimide, but is not limited thereto.

Embodiments of the present disclosure further provide a display, which includes: a substrate, having a first surface on which a plurality of self-luminous pixels are distributed; and a wavelength conversion matrix, including at least one wavelength conversion layer disposed on the first surface of the substrate. Each wavelength conversion layer of the at least one wavelength conversion layer includes a mask protection area and a dry etching area, the mask protection area corresponds to part of or all of the self-luminous pixels, and the wavelength conversion layer covers part of or all of the self-luminous pixels.

For example, the mask protection area covers part of or all of the plurality of self-luminous pixels. In some embodiments, the mask protection area may be the mask area mentioned above, and the dry etching area may be the non-mask area mentioned above.

In a specific embodiment, the substrate includes a silicon-based Complementary Metal Oxide Semiconductor (CMOS) or thin film field effect transistor, or the like.

In a specific embodiment, the self-luminous pixel include a micro light-emitting diode, where the plurality of self-luminous pixels are distributed in an array, and a spacing between the plurality of self-luminous pixels ranges from 1 μm to 100 μm.

In a specific embodiment, the plurality of self-luminous pixels includes a first self-luminous pixel, at least one wavelength conversion layer includes a first wavelength conversion layer, the first wavelength conversion layer correspondingly covers the first self-luminous pixel, and the first self-luminous pixel is configured to superimpose the first wavelength conversion layer to emit light with a first light wavelength.

In a specific embodiment, a first filter layer is disposed on the first wavelength conversion layer, and the first filter layer allows the light with the first light wavelength to pass through.

In a specific embodiment, the plurality of self-luminous pixels includes a first self-luminous pixel and a second self-luminous pixel, at least one wavelength conversion layer includes a first wavelength conversion layer and a second wavelength conversion layer, and the first wavelength conversion layer and the second wavelength conversion layer correspondingly cover the first self-luminous pixel and the second self-luminous pixel respectively. The first self-luminous pixel is configured to superimpose the first wavelength conversion layer to emit light with a first light wavelength, and the second self-luminous pixel is configured to superimpose the second wavelength conversion layer to emit light with a second light wavelength.

Wavelengths of light emitted by the first self-luminous pixel and by the second self-luminous pixel are the same or different, photoluminescent materials contained in the first wavelength conversion layer and in the second wavelength conversion layer are the same or different, and the light with the first light wavelength is different from the light with the second light wavelength.

In a specific embodiment, a first filter layer and a second filter layer are respectively disposed on the first wavelength conversion layer and the second wavelength conversion layer, the first filter layer allows the light with the first light wavelength to pass through, and the second filter layer allows the light with the second light wavelength to pass through.

In a specific embodiment, the plurality of self-luminous pixels further includes a third self-luminous pixel, and at least one wavelength conversion layer further includes a third wavelength conversion layer covering the third self-luminous pixel. The third self-luminous pixel is configured to superimpose the third wavelength conversion layer to emit light with a third light wavelength.

Wavelengths of light emitted by the first self-luminous pixel, by the second self-luminous pixel and by the third self-luminous pixel are the same or different, photoluminescent materials contained in the first wavelength conversion layer, in the second wavelength conversion layer and in the third wavelength conversion layer are the same or different, and the light with the first light wavelength, the light with the second light wavelength and the light with the third light wavelength are different.

In a specific embodiment, a third filter layer is disposed on the third wavelength conversion layer, and the third filter layer allows the light with the third light wavelength to pass through.

In a specific embodiment, the first filter layer, the second filter layer and the third filter layer include an organic color filter photoresist, an inorganic distributed drag reflector or the like, but are not limited thereto.

In a specific embodiment, a wavelength conversion material contained in the wavelength conversion layer includes a photoluminescent material, a polymer film material and a solvent.

In a specific embodiment, the photoluminescent material includes a phosphor or a quantum dot. The polymer film material includes any one or a combination of acrylic acid, polyethylene and resin. The solvent includes any one or a combination of propylene glycol methyl ether acetate, toluene or alcohol, but is not limited thereto. Specific contents of the photoluminescent material, the polymer film material and the solvent may be referred to related descriptions above, and may not be repeated here.

In a specific embodiment, a passivation layer is further disposed on the first surface of the substrate, the passivation layer fills a gap of the wavelength conversion matrix, and a surface of the passivation layer is flush with or lower than a surface of the wavelength conversion layer.

In a specific embodiment, a material of the passivation layer includes any one or a combination of an organic black matrix photoresist, a color filter photoresist and a polyimide, but is not limited thereto.

In a specific embodiment, an etching barrier layer is further disposed on the first surface of the substrate, and the wavelength conversion layer and the passivation layer are disposed on the etching barrier layer.

In a specific embodiment, a material of the etching barrier layer includes any one or a combination of silicon dioxide, silicon nitride and aluminum oxide, but is not limited thereto.

The display in embodiments of the present disclosure may be a micro-display or other display.

It should be noted that, light with a first wavelength provided by the self-luminous pixel is initial light, and the initial light may be monochromatic light, such as ultraviolet light, blue light, green light, etc.; of course, it may also be bicolor light, such as ultraviolet plus blue light, blue plus green light, etc.; and of course, it may also be white light, such as red-green-blue light, blue-yellow light, etc. If the initial light includes light with a specific wavelength required for the micro-display to be realized, a wavelength conversion material corresponding to this wavelength may be omitted. For example, if the initial light of the display panel (including a driving panel and self-luminous pixels) is blue, a corresponding blue wavelength conversion material does not need to be provided.

Generally, a wavelength of light converted by the wavelength conversion layer is longer than a wavelength of the initial light, and the light with a second wavelength formed after the conversion may be monochromatic light (such as blue light, green light, yellow light, red light, etc.), or polychromatic light (such as blue-green light, blue-red light, red-green light, blue-green-red light, etc.). For example, if the initial light of the display panel is blue light, it may be converted into a monochromatic green display by using only a green wavelength conversion material. Of course, a combination of any other colors is also possible, as long as a corresponding color conversion material is selected.

The technical solutions, implementation processes and principles of the technical solutions and the like are further explained below with reference to the accompanying drawings and specific embodiments. Unless otherwise specified, processes of epitaxy, coating, etching, etc. used in embodiments of the present disclosure may be known to a person skilled in the art.

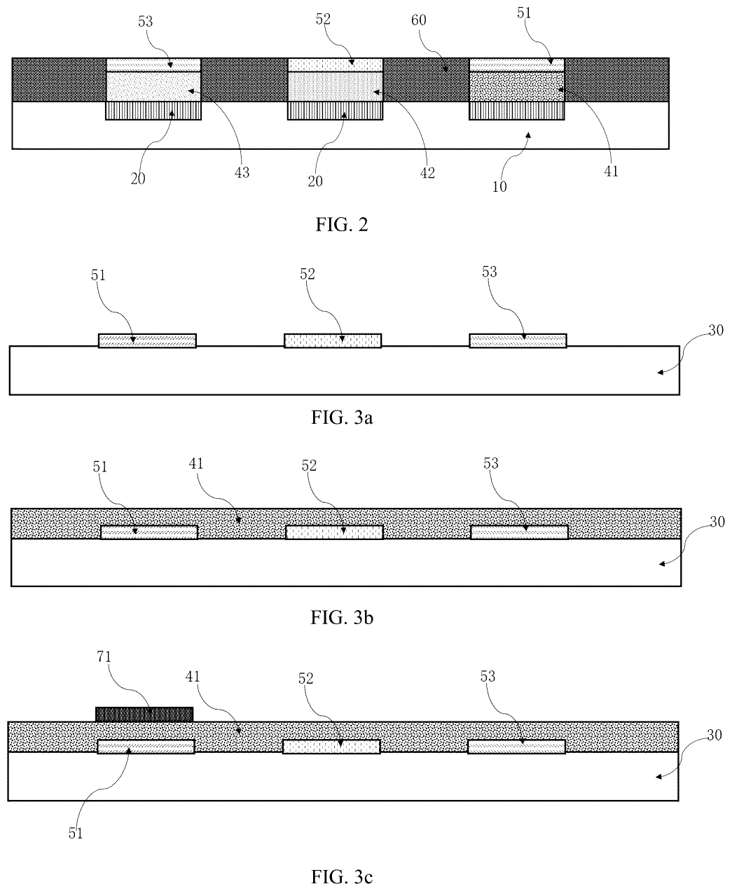

Referring to FIG. 2, embodiments of the present disclosure provide a wavelength conversion matrix, which includes wavelength conversion layers 41, 42 and 43 and a passivation layer 60 disposed on a surface of a driving panel 10. The surface of the driving panel 10 has self-luminous pixels 20, and the wavelength conversion layers 41, 42 and 43 and the passivation layer 60 are covered on the surface of the driving panel 10. The wavelength conversion layers 41, 42 and 43 correspond to the self-luminous pixels 20, and the wavelength conversion layers 41, 42 and 43 cover part of or all of the self-luminous pixels 20. The passivation layer 60 is disposed between the wavelength conversion layers 41, 42 and 43, and the wavelength conversion layers 41, 42 and 43 may be configured to superimpose the self-luminous pixels 20 of the display to emit light with a specific wavelength.

In this embodiment, the driving panel 10 may be a thin film field effect transistor, such as a silicon-based CMOS.

In this embodiment, the self-luminous pixel 20 may be a micro light-emitting diode or a micro-organic light-emitting diode, and the micro light-emitting diode is formed based on an inorganic semiconductor material. For example, the inorganic semiconductor material may be gallium nitride, aluminum gallium nitride, gallium arsenide, aluminum gallium indium phosphide, etc. The micro-organic light-emitting diode is formed based on an organic material, for example, the organic material may be a small molecule, a polymer, a phosphorescent material, etc.

In this embodiment, light with a first wavelength provided by the self-luminous pixel 20 is initial light, and the initial light may be monochromatic light, such as ultraviolet light, blue light, green light, etc.; of course, it may also be bicolor light, such as ultraviolet plus blue light, blue plus green light, etc.; and of course, it may also be white light, such as red-green-blue light, blue-yellow light, etc. If the initial light includes light with a specific wavelength required for the micro-display to be realized, a wavelength conversion layer (material) corresponding to the light with this wavelength may be omitted. For example, if the initial light of the display panel is blue, a corresponding blue wavelength conversion material does not need to be provided.

In this embodiment, a plurality of self-luminous pixels 20 may be provided, the plurality of self-luminous pixels 20 are distributed in a first area of the surface of the driving panel 10, and the plurality of self-luminous pixels 20 may be distributed in a patterned array. The first area may be considered to be a light-emitting area.

In this embodiment, a pixel spacing size of the self-luminous pixels 20 ranges from 1 μm to 100 μm, and a resolution of the self-luminous pixels 20 may be flexibly set, for example, VGA (640*480), XGA (1024*768), FHD (1920*1080), etc. Preferably, the spacing of the plurality of self-luminous pixels 20 may range from 1 μm to 5 μm.

In this embodiment, the wavelength conversion layers 41, 42 and 43 are disposed on a surface of the driving panel 10 and at least completely cover the plurality of self-luminous pixels 20. It can be understood that an orthographic projection of the wavelength conversion layer is completely overlapped with an orthographic projection of the self-luminous pixel 20, or the self-luminous pixel 20 is located in the orthographic projection of the wavelength conversion layer.

In this embodiment, a plurality of wavelength conversion layers may also be provided, the wavelength conversion layers 41, 42 and 43 may also be distributed in a patterned array, and a distribution pattern of the wavelength conversion layers 41, 42 and 43 is the same or similar to a distribution pattern of the self-luminous pixels 20. In an example, a mask area in the wavelength conversion layer may be regarded as a wavelength conversion unit, and a spacing between two adjacent wavelength conversion units in the wavelength conversion layer, that is, a length of a non-mask area between two adjacent mask areas in the wavelength conversion layer, may be range from 1 μm to 100 μm, preferably range from 1 μm to 5 μm. In an example, a size of each wavelength conversion unit may be range from 1 μm to 100 μm, preferably range from 1 μm to 5 μm. When the wavelength conversion unit is rectangular, the size of the wavelength conversion unit may be a side length of the wavelength conversion unit; and when the wavelength conversion unit is circular, the size of the wavelength conversion unit may be a diameter of the wavelength conversion unit.

In this embodiment, the wavelength conversion layers 41, 42 and 43 may be at least one of a red light wavelength conversion layer, a green light wavelength conversion layer, a blue light wavelength conversion layer and a yellow light wavelength conversion layer. For example, the wavelength conversion layer 41 is a red light wavelength conversion layer, the wavelength conversion layer 42 is a green light wavelength conversion layer and the wavelength conversion layer 43 is a blue light wavelength conversion layer.

It should be noted that a second wavelength of light obtained by conversion of the wavelength conversion layers 41, 42 and 43 is generally longer than a first wavelength of the initial light, and the light with the second wavelength formed after conversion may be monochromatic light (for example, blue light, green light, yellow light, red light, etc.) or polychromatic light (for example, blue-green light, blue-red light, red-green light, blue-green-red light, etc.). For example, if the initial light of the display panel is blue light, it may be converted into a monochromatic green display by using only a green wavelength conversion material. Of course, a combination of any other colors is also possible, as long as a corresponding color conversion material is selected.

In this embodiment, the passivation layer 60 is disposed in a second area of the surface of the driving panel 10, that is, it can be understood that the passivation layer 60 is disposed in a gap between the wavelength conversion layers 41, 42 and 43. A thickness of the passivation layer 60 may be consistent with a thickness of each of the wavelength conversion layers 41, 42 and 43. A material of the passivation layer may be a photoresist, for example, may be an organic black matrix photoresist, a color filter photoresist, etc, and a specific material may be polyimide or the like.

In this embodiment, filter layers 51, 52 and 53 are further disposed on the corresponding wavelength conversion layers 41, 42 and 43, and the filter layers 51, 52 and 53 allow light with a second wavelength formed by conversion of the wavelength conversion layers 41, 42 and 43 to pass through, but prevent light with a first wavelength from passing through.

In this embodiment, the filter layers 51, 52 and 53 may be at least one of a red light filter layer, a green light filter layer, a blue light filter layer and a yellow light filter layer. For example, the filter layer 51 may be a red light filter layer, the filter layer 52 may be a green light filter layer and the filter layer 53 may be a blue light filter layer.

In this embodiment, the filter layers 51, 52 and 53 may be organic color filter photoresists or inorganic distributed drag reflectors (for example, multi-layer silicon dioxide/titanium dioxide deposited by electron beam evaporation or chemical vapor deposition), or the like.

It should be noted that, if the wavelength conversion layer may absorb most of the initial light, a corresponding filter layer may not be disposed any more.

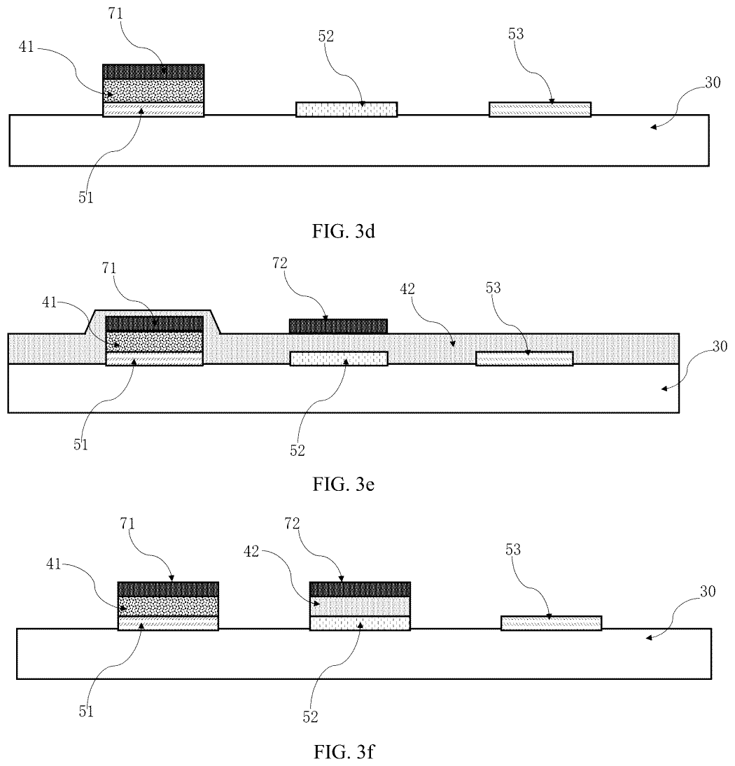

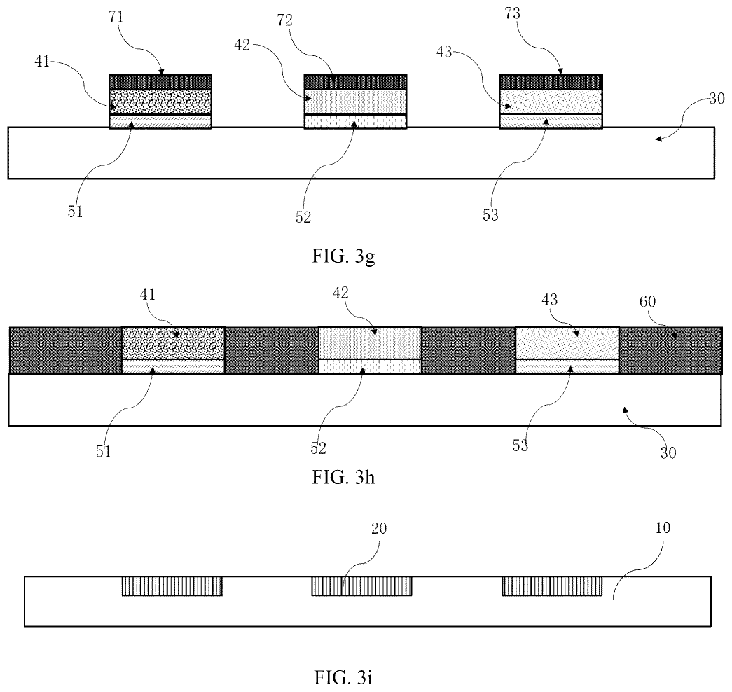

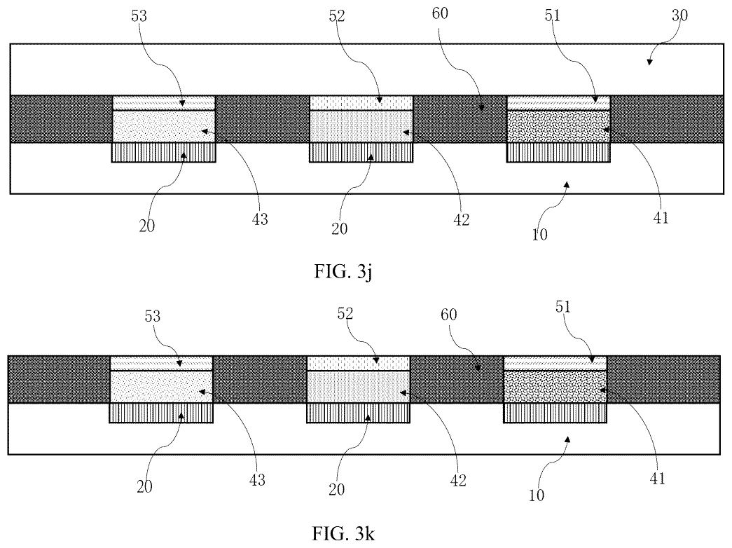

Referring to FIG. 3a to FIG. 3k, a manufacturing method for a wavelength conversion matrix applied for a micro-display apparatus (eg, a micro-display) includes the following steps.

1) Providing a second substrate 30, and disposing a plurality of filter layers 51/52/53 on a second surface of the second substrate 30, so as to form a device structure shown in FIG. 3a.

It should be noted that the second substrate 30 is a transparent substrate, for example, the second substrate 30 may be a sapphire substrate, a glass substrate (ordinary glass or quartz glass), or the like. The plurality of filter layers 51/52/53 may be formed directly by a selective area manufacturing manner, or may be formed by first disposing a filter material on the second surface of the second substrate and then etching the filter material through dry etching. The filter layer 51 may be a red filter layer, the filter layer 52 may be a green filter layer, the filter layer 53 may be a blue filter layer, and the plurality of filter layers 51/52/53 may be distributed in an array.

2) Coating a wavelength conversion material on the second surface of the second substrate 30 and surfaces of the filter layers 51/52/53 to form a wavelength conversion layer after curing, then covering a mask on a surface of the wavelength conversion layer, and removing a remaining part of the wavelength conversion layer that is not protected by the mask through dry etching, so as to form a wavelength conversion matrix including a plurality of wavelength conversion layers 41/42/43.

The wavelength conversion matrix includes a plurality of wavelength conversion layers distributed at intervals, the plurality of wavelength conversion layers respectively correspond to the plurality of filter layers, and a corresponding relationship may be one-to-one or one-to-many. It should be noted that wavelength conversion materials included in the plurality of wavelength conversion layers may be the same or different, and filter materials included in the plurality of filter layers may be the same or different.

Step 2) may specifically include the following steps.

2.1) As shown in FIG. 3b, coating a red wavelength conversion material (may also referred to as red light wavelength conversion material) on the second surface of the second substrate 30 and a surface of the red filter layer 51/the green filter layer 52/the blue filter layer 53 to form a red (red light) wavelength conversion layer 41 after curing, or, in order to precisely control the subsequent etching process and precision, according to specific conditions, disposing an etching barrier layer or a mask on the second surface of the second substrate 30 and surfaces of the green filter layer 52 and the blue filter layer 53, then forming a red wavelength conversion layer 41 on surfaces of the etching barrier layer/the mask and the red filter layer 51, and removing the etching barrier layer or the mask located on the green filter layer 52 and the blue filter layer 53 to fabricate the green wavelength conversion layer 42 and the blue wavelength conversion layer 43 after the red wavelength conversion layer 41 is etched. Subsequent manufacturing of the green wavelength conversion layer 42 may refer to this process.

2.2) As shown in FIG. 3c, disposing a first mask 71 on the red wavelength conversion layer 41, where the first mask 71 covers a first area of the red wavelength conversion layer 41. It should be noted that the first area corresponds to the red filter layer 51, which means that a shape, an area and a distribution pattern of the first mask 71 is the same as a shape, an area and a distribution pattern of the red filter layer 51, respectively. Situations of the green filter layer 52 and the blue filter layer 53 are similar to this situation of the red filter layer 51.

2.3) As shown in FIG. 3d, removing a part of the red wavelength conversion layer 41 that is not covered by the first mask 71 through dry etching, where a remaining red wavelength conversion layer 41 is corresponding disposed on the red filter layer 51.

2.4) As shown in FIG. 3e, coating a green (green light) wavelength conversion material on the second surface of the second substrate 30 and surfaces of the green filter layer 52, the blue filter layer 53 and the first mask 71 to form a green (green light) wavelength conversion layer 42 after curing, and disposing a second mask 72 on the green wavelength conversion layer 42, where the second mask 72 covers a second area of the green wavelength conversion layer 42. It should be noted that the second area corresponds to the green filter layer 52, and there is no overlapping area between an orthographic projection area of the second mask 72 and an orthographic projection area of the first mask 71.

2.5) As shown in FIG. 3f, removing a part of the green wavelength conversion layer 42 that is not covered by the second mask 72 through dry etching, where a remaining green wavelength conversion layer 42 is corresponding disposed on the green filter layer 52.

2.6) As shown in FIG. 3g, coating a blue (blue light) wavelength conversion material on the second surface of the second substrate 30 and surfaces of the blue filter layer 53, the first mask 71 and the second mask 72 to form a blue (blue light) wavelength conversion layer 43 after curing; and disposing a third mask 73 on the blue wavelength conversion layer 43, where the third mask 73 covers a third area of the blue wavelength conversion layer 43. It should be noted that the third area corresponds to the blue filter layer 53, and there is no overlapping area between an orthographic projection area of the third mask 73 and orthographic projection areas of the first mask 71 and the second mask 72. Then, a part of the blue wavelength conversion layer 43 that is not covered by the third mask 73 is removed through dry etching, and a remaining blue wavelength conversion layer 43 is correspondingly disposed on the blue filter layer 53.

It should be noted that the red, green or blue wavelength conversion material includes a photoluminescent material, a polymer film material and a solvent.

Specific contents of the photoluminescent material, the polymer film material and the solvent may be referred to related descriptions above, and may not be repeated here.

In this embodiment, the first, second, and third masks may be dielectric material masks, photoresist masks, metal masks, or the like. A material of the dielectric material mask may be silicon dioxide, silicon nitride, aluminum oxide or the like. The metal mask may be a plurality of metal layers which are stacked, and a material of the metal layer includes cadmium, aluminum, nickel, gold, titanium, platinum or the like. A manner of dry etching may be referred to the descriptions in the above manufacturing method for the wavelength conversion matrix.

3) As shown in FIG. 3h, forming a passivation layer 60 on the second surface of the second substrate 30, and making a surface of the passivation layer 60 be flush with the surfaces of the red wavelength conversion layer 41, the green wavelength conversion layer 42 and the blue wavelength conversion layer 43, where the passivation layer 60 is disposed in a gap between the red wavelength conversion layer 41, the green wavelength conversion layer 42 and the blue wavelength conversion layer 43. It should be noted that the first mask 71, the second mask 72 and the third mask 73 may be removed first, and then the passivation layer 60 is formed. Of course, the passivation layer may be formed first, and then the first mask 71, the second mask 72 and the third mask 73 are removed.

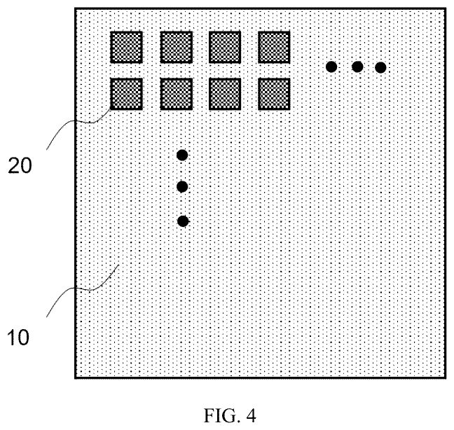

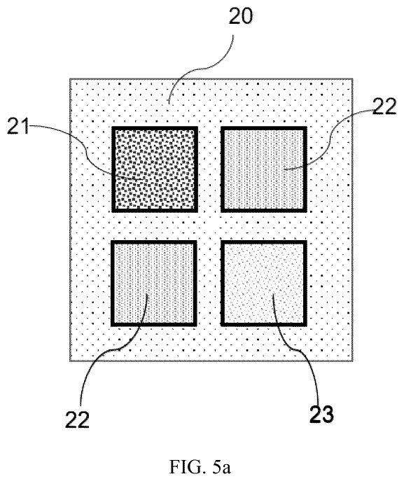

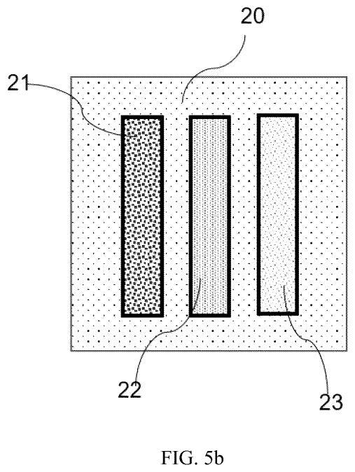

4) As shown in FIG. 3i, providing a first substrate (may also be referred to as a driving panel) 10, where the first substrate 10 has a first surface, a plurality of self-luminous pixels 20 are distributed on the first surface, and the self-luminous pixels 20 may provide light with a first wavelength. The plurality of self-luminous pixels 20 may be distributed in a patterned array, and the self-luminous pixels 20 may be full-color pixels. For example, a distribution pattern of the plurality of self-luminous pixels 20 may be as shown in FIG. 4, an arrangement of the red, green and blue pixels in the full-color pixels may be as shown in FIG. 5a, FIG. 5b and FIG. 5c, 21 in the figures is the red pixel, 22 in the figures is the green pixel, 23 in the figures is the blue pixel, and the arrangement of pixels may be flexibly adjusted without special limitation.

5) As shown in FIG. 3j, combining the wavelength conversion matrix and the passivation layer 60 on the second surface of the second substrate 30 with the first surface of the first substrate 10, ang making the wavelength conversion matrix cover part of or all of self-luminous pixels 20. For example, a red wavelength conversion layer 41 in the wavelength conversion matrix corresponding covers a red pixel 21, a green wavelength conversion layer 42 corresponding covers a green pixel 22, and a blue wavelength conversion layer 43 corresponding covers a blue pixel 23.

6) As shown in FIG. 3k, removing the second substrate 30 to expose the wavelength conversion array and the passivation layer 60, so as to form the micro-display apparatus.

Embodiments of the present disclosure provide a manufacturing method for the wavelength conversion matrix applied for the micro-display apparatus, which has simple process flow, and is easy to operate and better in controllability. In the manufacturing method provided by the present disclosure, patterning of the wavelength conversion layer is realized by dry etching, so as to make resolution and conversion efficiency of the finally formed wavelength conversion layer higher, which is beneficial to realizing micro-display of high resolution and high pixel density of the micro-display apparatus, thereby improving a display effect of a display device.

According to a manufacturing method for the wavelength conversion matrix applied for the micro-display apparatus provided by embodiments of the present disclosure, a pattern of the wavelength conversion layer is obtained through dry etching, and an etching mask is defined by using a high-resolution photoresist through another lithography step and a metallization step, so that the resolution of the obtained wavelength conversion matrix is higher. Furthermore, a photoluminescent material in the manufacturing method for the wavelength conversion matrix applied for the micro-display apparatus provided by embodiments of the present disclosure may be dispersed in the polymer film material with a relatively high concentration. On this basis, a relatively thick photoluminescent material film may be implemented by adjusting photolithography and dry etching process parameters, thereby obtaining high conversion efficiency.

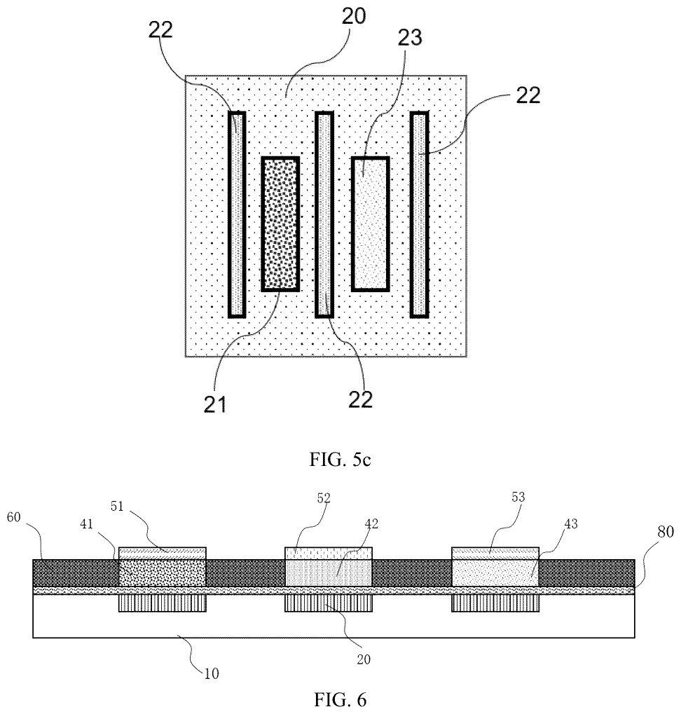

Referring to FIG. 6, embodiments of the present disclosure provides a display, which includes a driving panel 10, a self-luminous pixel 20, an etching barrier layer 80, wavelength conversion layers 41, 42 and 43 and a passivation layer 60. The self-luminous pixel 20 is disposed on the driving panel 10, the etching barrier layer 80 is disposed on the driving panel 10 and covers the self-luminous pixel 20. The wavelength conversion layers 41, 42 and 43 and the passivation layer 60 are disposed on the etching barrier layer 80, the wavelength conversion layers 41, 42 and 43 correspond to the self-luminous pixels 20, and the passivation layer 60 is disposed between the plurality of wavelength conversion layers 41, 42 and 43. The self-luminous pixels 20 may superimpose the wavelength conversion layers 41, 42 and 43 to emit light with a specific wavelength.

In a specific embodiment, the driving panel 10 may be a thin film field effect transistor, such as a silicon-based CMOS.

In a specific embodiment, the self-luminous pixel 20 may be a micro light-emitting diode or a micro organic light-emitting diode. Specific contents of the self-luminous pixel 20 may be referred to related descriptions above (for example, embodiments corresponding to FIG. 2).

In a specific embodiment, the etching barrier layer 80 may protect a display panel (the display panel includes the driving panel and the self-luminous pixel) at the bottom during the dry etching process of the wavelength conversion layer, and a material of the etching barrier layer 80 may be an inorganic semiconductor material, such as silicon dioxide, silicon nitride, aluminum oxide.

In a specific embodiment, the wavelength conversion layers 41, 42 and 43 are disposed on the etching barrier layer 80, and at least completely cover the self-luminous pixels 20. It can be understood that an orthographic projection of the wavelength conversion layer is completely overlapped with an orthographic projection of the self-luminous pixel 20, or the self-luminous pixel 20 is located in the orthographic projection of the wavelength conversion layer.

In a specific embodiment, a plurality of wavelength conversion layers may be disposed, the wavelength conversion layers 41, 42 and 43 may also be distributed in a patterned array, and a distribution pattern of the wavelength conversion layers 41, 42 and 43 is the same or similar to a distribution pattern of the self-luminous pixels 20.

In a specific embodiment, the wavelength conversion layers 41, 42 and 43 may be at least one of a red light wavelength conversion layer, a green light wavelength conversion layer, a blue light wavelength conversion layer and a yellow light wavelength conversion layer. For example, the wavelength conversion layer 41 is a red light wavelength conversion layer, the wavelength conversion layer 42 is a green light wavelength conversion layer and the wavelength conversion layer 43 is a blue light wavelength conversion layer.

Specific contents of the wavelength conversion layers 41, 42 and 43 may be referred to related descriptions above (for example, embodiments corresponding to FIG. 2).

In a specific embodiment, the passivation layer 60 is disposed in a second area of the etching barrier layer 80, that is, it can be understood that the passivation layer 60 is disposed on a gap between the wavelength conversion layers 41, 42 and 43. A thickness of the passivation layer 60 may be consistent with a thickness of each of the wavelength conversion layers 41, 42 and 43. A material of the passivation layer may be a photoresist, for example, may be an organic black matrix photoresist, a color filter photoresist, etc, and a specific material may be polyimide or the like.

In a specific embodiment, filter layers 51, 52 and 53 are further disposed on the corresponding wavelength conversion layers 41, 42 and 43, and the filter layers 51, 52 and 53 allow light with a second wavelength formed by conversion of the wavelength conversion layers 41, 42 and 43 to pass through, but prevent light with a first wavelength from passing through.

In a specific embodiment, the filter layers 51, 52 and 53 may be at least one of a red light filter layer, a green light filter layer, a blue light filter layer and a yellow light filter layer. For example, the filter layer 51 may be a red light filter layer, the filter layer 52 may be a green light filter layer and the filter layer 53 may be a blue light filter layer.

In a specific embodiment, the filter layers 51, 52 and 53 may be organic color filter photoresists or inorganic distributed drag reflectors (for example, multi-layer silicon dioxide/titanium dioxide deposited by electron beam evaporation or chemical vapor deposition), or the like.

It should be noted that, if the wavelength conversion layer may absorb most of the initial light, a corresponding filter layer may not be disposed any more.

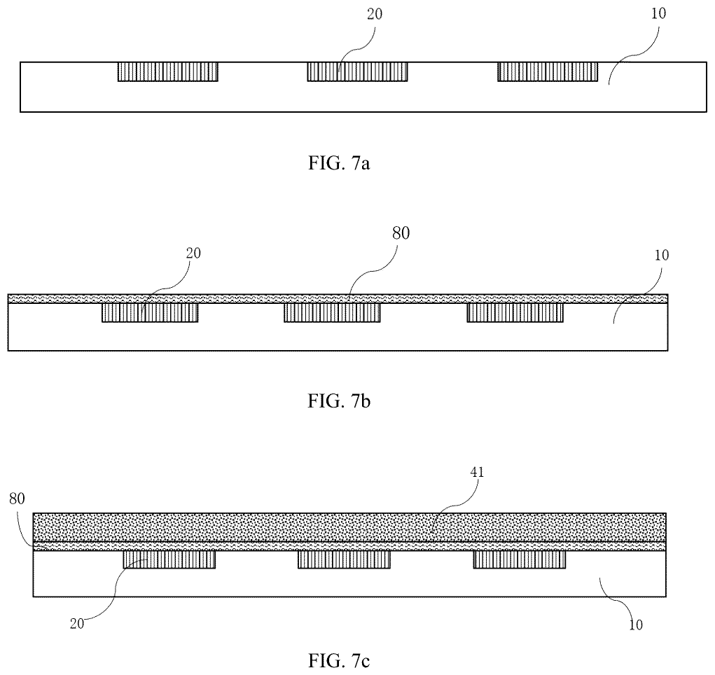

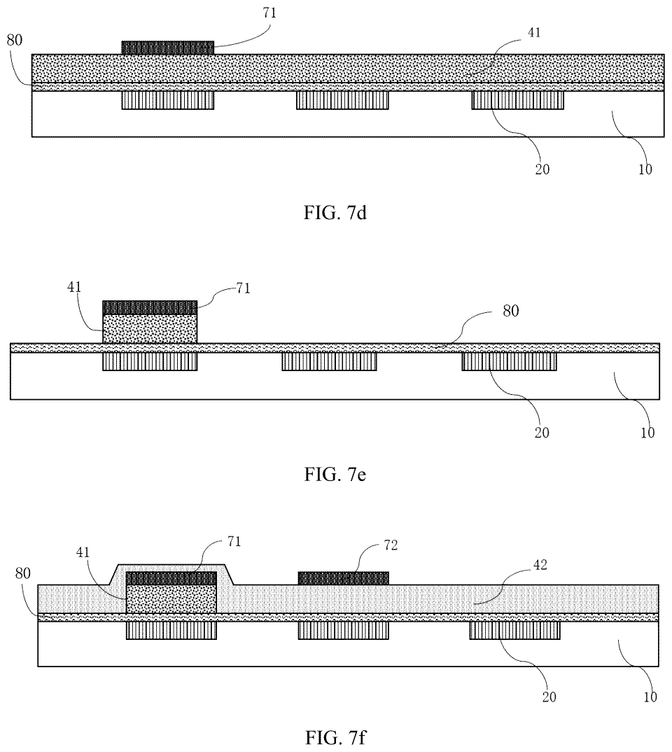

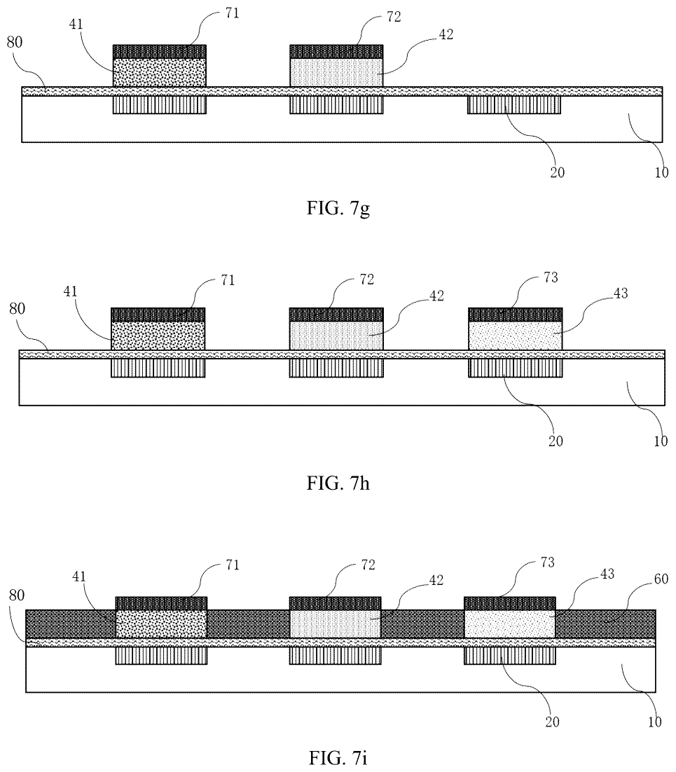

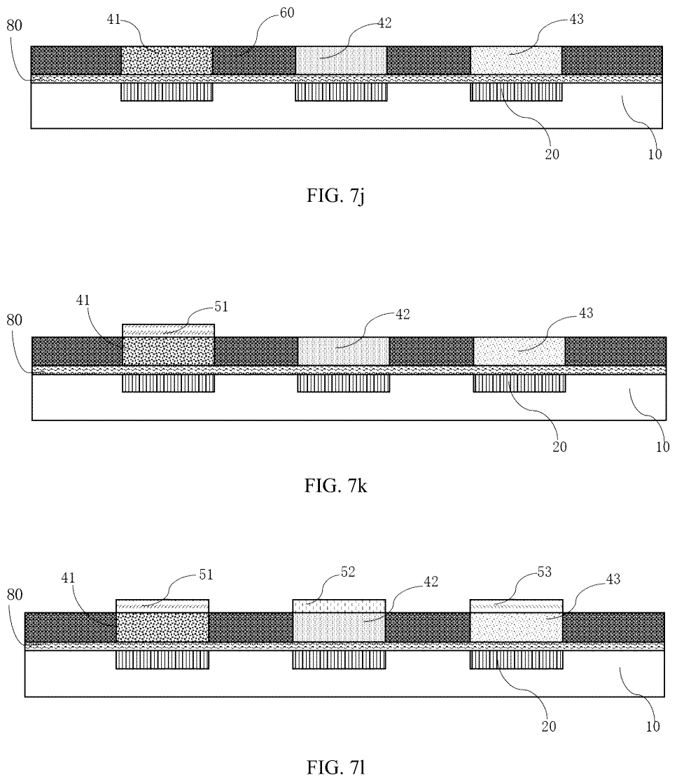

Referring to FIG. 7a to FIG. 7l, a manufacturing method for a wavelength conversion matrix (or a manufacturing method for a display) applied for a display (such as a micro-display) includes the following steps.

1) Referring to FIG. 7a, providing a display panel, where the display panel includes a driving panel 10 and a plurality of self-luminous pixels 20 disposed on the driving panel 10. The self-luminous pixels 20 may provide light with a first wavelength. The plurality of self-luminous pixels 20 may be distributed in a patterned array, and the self-luminous pixels 20 may be full-color pixels. For example, a distribution pattern of the plurality of self-luminous pixels 20 may be as shown in FIG. 4, an arrangement of the red, green and blue pixels in the full-color pixels may be as shown in FIG. 5a, FIG. 5b and FIG. 5c, 21 in the figures is the red pixel, 22 in the figures is the green pixel, 23 in the figures is the blue pixel, and the arrangement of pixels may be flexibly adjusted without special limitation.

It should be noted that one side surface of the driving panel that is provided with the self-luminous pixel 20 may serve as a light-emitting surface.

2) Referring to FIG. 7b, forming an etching barrier layer 80 on a light-emitting surface of the driving panel 10. The etching barrier layer 80 may protect the display panel (the display panel includes the driving panel and the self-luminous pixel) at the bottom during the dry etching process of the wavelength conversion layer, and a material of the etching barrier layer 80 may be an inorganic semiconductor material, such as silicon dioxide, silicon nitride, aluminum oxide.

3) Referring to FIG. 7c, coating a red wavelength conversion material (may also be referred to as a red light wavelength conversion material) on a surface of the etching barrier layer 80 to form a red (red light) wavelength conversion layer 41 after curing.

4) Referring to FIG. 7d, disposing a first mask 71 on the red wavelength conversion layer 41, where the first mask 71 covers a part of the red wavelength conversion layer 41. It should be noted that the first mask 71 corresponds to a part of the self-luminous pixels 20, which means that a shape, an area and a distribution pattern of the first mask 71 is the same as a shape, an area and a distribution pattern of the part of the self-luminous pixels 20, respectively.

5) Referring to FIG. 7e, removing a part of the red wavelength conversion layer 41 that is not covered by the first mask 71 through dry etching, where a remaining red wavelength conversion layer 41 is corresponding disposed on the part of the self-luminous pixels 20. Specific contents of dry etching may be referred to related descriptions above.

Referring to FIG. 7f, coating a green (green light) wavelength conversion material on the surface of the etching barrier layer 80 to form a green (green light) wavelength conversion layer 42 after curing, and then disposing a second mask 72 on the green wavelength conversion layer 42, where the second mask 72 covers a part of the green wavelength conversion layer 42. It should be noted that the second mask 72 corresponds to a part of the self-luminous pixels 20, which means that a shape, an area and a distribution pattern of the second mask 72 is the same as a shape, an area and a distribution pattern of the part of the self-luminous pixels 20, respectively, and there is no overlapping area between an orthographic projection area of the second mask 72 and an orthographic projection area of the first mask 71.

7) Referring to FIG. 7g, removing a part of the green wavelength conversion layer 42 that is not covered by the second mask 72 through dry etching, where a remaining green wavelength conversion layer 42 is correspondingly disposed on the part of the self-luminous pixels 20.

8) Referring to FIG. 7h, and steps 3) to 5) or steps 6) to 7), coating a blue (blue light) wavelength conversion material on the surface of the etching barrier layer 80 to form a blue (blue light) wavelength conversion layer 43 after curing, and disposing a third mask 73 on the blue wavelength conversion layer 43, where the third mask 73 covers a part of the blue wavelength conversion layer 43. It should be noted that the third mask 73 corresponds to a part of the self-luminous pixels 20, which means that a shape, an area and a distribution pattern of the third mask 73 is the same as a shape, an area and a distribution pattern of the part of the self-luminous pixels 20, respectively. Moreover, there is no overlapping area between an orthographic projection area of the third mask 73 and orthographic projection areas of the first mask 71 and the second mask 72. Then, a part of the blue wavelength conversion layer 43 that is not covered by the third mask 73 is removed through dry etching, and a remaining blue wavelength conversion layer 43 is correspondingly disposed on the part of the self-luminous pixels 20.

10) Referring to FIG. 7i, forming a passivation layer 60 on the surface of the etching barrier layer 80, where the passivation layer 60 is disposed on a gap between the red wavelength conversion layer 41, the green wavelength conversion layer 42 and the blue wavelength conversion layer 43.

11) Referring to FIG. 7j, removing the first mask 71, the second mask 72 and the third mask 73.

Referring to FIG. 7k and FIG. 7l, respectively forming a red (red light) filter layer 51, a green (green light) filter layer 52 and a blue (blue light) filter layer 53 on the red wavelength conversion layer 41, the green wavelength conversion layer 42 and the blue wavelength conversion layer 43.

It should be noted that each of the red, green and blue wavelength conversion materials includes a photoluminescent material, a polymer film material and a solvent.

Specific contents of the photoluminescent material, the polymer film material and the solvent may be referred to related descriptions above, and may not be repeated here.

In a specific embodiment, the first, second and third masks include semiconductor masks, photoresist masks or metal masks. A material of the semiconductor mask may be silicon dioxide, silicon nitride, aluminum oxide or the like. The metal mask may be a plurality of metal layers which are stacked, and a material of the metal layer includes cadmium, aluminum, nickel, gold, titanium, platinum or the like.

In a specific embodiment, the red, green and blue filter layers include organic color filter photoresists, inorganic distributed drag reflectors, or the like.

Embodiments of the present disclosure provide a manufacturing method for the wavelength conversion matrix applied for the micro-display, which has simple process flow, and is easy to operate and better in controllability. In the manufacturing method provided by the present disclosure, patterning of the wavelength conversion layer is realized by dry etching, so as to make resolution and conversion efficiency of the finally formed wavelength conversion layer higher, which is beneficial to realizing micro-display of high resolution and high pixel density of a micro-display device, thereby improving a display effect of the display device.

According to a manufacturing method for the wavelength conversion matrix applied for the micro-display provided by embodiments of the present disclosure, a pattern of the wavelength conversion layer is obtained through dry etching, and an etching mask is defined by using a high-resolution photoresist through another lithography step and a metallization step, so that the resolution of the obtained wavelength conversion matrix is higher. Furthermore, a photoluminescent material in the manufacturing method for the wavelength conversion matrix applied for the micro-display provided by embodiments of the present disclosure may be dispersed in the polymer film material with a relatively high concentration. On this basis, a relatively thick photoluminescent material film may be implemented by adjusting photolithography and dry etching process parameters, thereby obtaining high conversion efficiency.

It should be understood that the above embodiments are merely used to explain the technical concepts and characteristics of the present disclosure, which are intended to enable a person skilled in the art to understand the content of the present disclosure and implement the present disclosure, and can not limit the protection scope of the present disclosure. All equivalent changes or modifications made according to the spirit of the present disclosure shall fall within the protection scope of the present disclosure.

What is claimed is:

1. A wavelength conversion matrix, comprising:
at least one wavelength conversion layer that is dry-etchable, wherein each wavelength conversion layer of the at least one wavelength conversion layer comprises a mask area and a non-mask area, the non-mask area is a hollow area, the wavelength conversion layer is configured to superimpose a self-luminous pixel of a display to emit light with a set light wavelength, the at least one wavelength conversion layer comprises a first wavelength conversion layer, and the first wavelength conversion layer is configured to superimpose a first self-luminous pixel of the display to emit light with a first light wavelength.

2. The wavelength conversion matrix according to claim 1, wherein a first filter layer is disposed on the first wavelength conversion layer, and the first filter layer allows the light with the first light wavelength to pass through.

3. The wavelength conversion matrix according to claim 1, wherein the at least one wavelength conversion layer further comprises a second wavelength conversion layer, the second wavelength conversion layer is configured to superimpose a second self-luminous pixel of the display to emit light with a second light wavelength, and the light with the first light wavelength is different from the light with the second light wavelength.

4. The wavelength conversion matrix according to claim 1, wherein a passivation layer is disposed in the non-mask area, and a surface of the passivation layer is flush with or lower than a surface of the wavelength conversion layer.

5. A display, comprising:
a substrate, having a first surface on which a plurality of self-luminous pixels are distributed; and
a wavelength conversion matrix, comprising at least one wavelength conversion layer disposed on the first surface of the substrate, wherein each wavelength conversion layer of the at least one wavelength conversion layer comprises a mask protection area and a dry etching area, the mask protection area covers part of or all of the plurality of self-luminous pixels, the plurality of self-luminous pixels comprises a first self-luminous pixel, the at least one wavelength conversion layer comprises a first wavelength conversion layer, the first wavelength conversion layer correspondingly covers the first self-luminous pixel, and the first self-luminous pixel is configured to superimpose the first wavelength conversion layer to emit light with a first light wavelength.

6. The display according to claim 5, wherein each self-luminous pixel of the plurality of self-luminous pixels comprises a micro light-emitting diode, the plurality of self-luminous pixels are distributed in an array, and a spacing between the plurality of self-luminous pixels ranges from 1 μm to 100 μm.

7. The display according to claim 5, wherein a first filter layer is disposed on the first wavelength conversion layer, and the first filter layer allows the light with the first light wavelength to pass through.

8. The display according to claim 5, wherein the plurality of self-luminous pixels further comprises a second self-luminous pixel, the at least one wavelength conversion layer further comprises a second wavelength conversion layer, the second wavelength conversion layer correspondingly covers the second self-luminous pixel, the second self-luminous pixel is configured to superimpose the second wavelength conversion layer to emit light with a second light wavelength, and the light with the first light wavelength is different from the light with the second light wavelength.

9. The display according to claim 5, wherein an etching barrier layer is disposed between the first surface of the substrate and the wavelength conversion layer.

10. A manufacturing method for a wavelength conversion matrix, comprising:
disposing a wavelength conversion layer on a surface of a substrate;
disposing a mask on a surface of the wavelength conversion layer; and
removing a remaining part of the wavelength conversion layer except a part of the wavelength conversion layer protected by the mask through dry etching to form a wavelength conversion matrix.

11. The manufacturing method according to claim 10, further comprising:
disposing a passivation layer on the surface of the substrate to make the passivation layer fill a gap of the wavelength conversion matrix, and make a surface of the passivation layer be flush with or lower than the surface of the wavelength conversion layer.

12. The manufacturing method according to claim 10, wherein the wavelength conversion layer comprises a first wavelength conversion layer, and the disposing a wavelength conversion layer on a surface of a substrate comprises: disposing the first wavelength conversion layer on the surface of the substrate,
wherein the disposing a mask on a surface of the wavelength conversion layer comprises: disposing a first mask in a first area of a surface of the first wavelength conversion layer,
wherein the removing a remaining part of the wavelength conversion layer except a part of the wavelength conversion layer protected by the mask through dry etching to form a wavelength conversion matrix comprises: removing a remaining part of the first wavelength conversion layer except a part of the first wavelength conversion layer protected by the first mask through dry etching to form the wavelength conversion matrix,
wherein the first wavelength conversion layer is configured to superimpose a first self-luminous pixel of a display to emit light with a first light wavelength.

13. The manufacturing method according to claim 12, further comprising:
disposing a first filter layer on the surface of the substrate before disposing the first wavelength conversion layer,
wherein the first wavelength conversion layer at least covers the first filter layer, the first mask corresponds to the first filter layer, and the first filter layer allows the light with the first light wavelength to pass through.

14. The manufacturing method according to claim 12, wherein the wavelength conversion layer further comprises a second wavelength conversion layer, and the disposing a wavelength conversion layer on a surface of a substrate further comprises: disposing the second wavelength conversion layer on the surface of the substrate after removing the remaining part of the first wavelength conversion layer except the part of the first wavelength conversion layer protected by the first mask through dry etching,
wherein the disposing a mask on a surface of the wavelength conversion layer further comprises: disposing a second mask on a second area of a surface of the second wavelength conversion layer,
wherein the removing a remaining part of the wavelength conversion layer except a part of the wavelength conversion layer protected by the mask through dry etching to form a wavelength conversion matrix further comprises: removing a remaining part of the second wavelength conversion layer except a part of the second wavelength conversion layer protected by the second mask through dry etching to form the wavelength conversion matrix,
wherein the second wavelength conversion layer is configured to superimpose a second self-luminous pixel of the display to emit light with a second light wavelength, and
the manufacturing method further comprises: removing the mask after forming the wavelength conversion matrix.

15. The manufacturing method according to claim 14, further comprising: disposing a first filter layer and a second filter layer on the surface of the substrate before disposing the first wavelength conversion layer,
wherein the first wavelength conversion layer at least covers the first filter layer, the first mask corresponds to the first filter layer, the second wavelength conversion layer at least covers the second filter layer, the second mask corresponds to the second filter layer, the first filter layer allows the light with the first light wavelength to pass through, and the second filter layer allows the light with the second light wavelength to pass through.

16. The manufacturing method according to claim 10, wherein a plurality of self-luminous pixels are distributed on the surface of the substrate, and the mask is disposed corresponding to at least part of the plurality of self-luminous pixels.

17. The manufacturing method according to claim 16, wherein the disposing a wavelength conversion layer on a surface of a substrate comprises:
disposing an etching barrier layer on the surface of the substrate; and
disposing the wavelength conversion layer on a surface of the etching barrier layer.

18. The manufacturing method according to claim 16, further comprising:
forming a passivation layer on the surface of the substrate, wherein a gap of the wavelength conversion matrix is filled with the passivation layer, and a surface of the passivation layer is flush with or lower than the surface of the wavelength conversion layer.

19. The manufacturing method according to claim 16, wherein the plurality of self-luminous pixels comprise a first self-luminous pixel, and the wavelength conversion layer comprises a first wavelength conversion layer,
wherein the disposing a wavelength conversion layer on a surface of a substrate comprises: disposing the first wavelength conversion layer on the surface of the substrate,
wherein the disposing a mask on a surface of the wavelength conversion layer comprises: disposing a first mask in a first area of a surface of the first wavelength conversion layer, wherein the first area is disposed corresponding to the first self-luminous pixel,
wherein the removing a remaining part of the wavelength conversion layer except a part of the wavelength conversion layer protected by the mask through dry etching to form a wavelength conversion matrix comprises: removing a remaining part of the first wavelength conversion layer except a part of the first wavelength conversion layer protected by the first mask through dry etching to form the wavelength conversion matrix,
wherein the first self-luminous pixel is configured to superimpose the first wavelength conversion layer to emit light with a first light wavelength.

20. The manufacturing method according to claim 19, further comprising:
disposing a first filter layer on the first wavelength conversion layer, wherein the first filter layer allows the light with the first light wavelength to pass through.
